(19) United States
(12) Patent Application Publication
(10) Pub. No.: US 2020/0357722 A1
(43) Pub. Date: Nov. 12, 2020

(54) HEAT DISSIPATION APPARATUS FOR SURFACE-MOUNT POWER SEMICONDUCTOR DEVICES

(71) Applicants: Paul F. Carosa, San Dimas, CA (US); David L. Bogdanchik, San Dimas, CA (US)

(72) Inventors: Paul F. Carosa, San Dimas, CA (US); David L. Bogdanchik, San Dimas, CA (US)

(21) Appl. No.: 16/508,278

(22) Filed: Jul. 10, 2019

Related U.S. Application Data
(60) Provisional application No. 62/696,808, filed on Jul. 11, 2018.

(51) Int. Cl. H01L 23/473; H01L 25/00; H01L 23/498

(52) U.S. Cl. CPC H01L 23/473; H01L 23/49811; H01L 25/00

(57) ABSTRACT

An improved, liquid cooled, power semiconductor heat dissipation apparatus configured to accommodate surface-mount power semiconductor devices mounted on direct bond copper plates which are in thermal communication with a heat transfer surface and electrical communication with a printed circuit board or other surface on which the apparatus is mounted.

### CROSS-REFERENCE TO RELATED APPLICATIONS

This United States Non-Provisional Utility Patent Application claims the priority date of United States Provisional Application No: 62/696,808, titled: “MODULAR PACKAGING, COOLING AND CONNECTION METHOD AND APPARATUS FOR POWER SEMICONDUCTOR DEVICES,” filed Jul. 11, 2018 in the United States Patent and Trademark Office, the disclosure of which is hereby incorporated by reference in its entirety.

### FIELD OF THE PRESENT DISCLOSURE

This disclosure relates generally to a heat dissipation apparatus for power semiconductor devices, and more specifically to an improved heat dissipation apparatus for accommodating surface-mount power semiconductor devices.

### BACKGROUND OF THE RELATED ART

In any apparatus that contains power semiconductor devices, such as switches or rectifiers, heat dissipation is a critical issue. Excessive heat can lead to deterioration of both physical and electrical properties which in turn can cause both intermittent and permanent failures. Even within tolerable heat ranges, cooler operating temperatures are almost always desirable because cooler operating temperatures typically lead to increased electrical efficiency which, depending on the performance demands on a particular device, may allow a device to operate longer, consume less power, tolerate or endure higher power, or even be redesigned to be made physically smaller. In some fields of technology these advantages are of critical importance, so even marginal increases in heat dissipation efficiency may be of great competitive importance.

To achieve lower operating temperatures, power semiconductor devices are typically coupled with a heat sink or a heat dissipation device of some variety. The most efficient heat dissipation devices typically involve a thermally conductive material in physical contact or in close physical proximity to a power semiconductor device which is capable of drawing heat out of a power semiconductor device and transferring the heat energy away from its source for dispersion or dissipation in a more convenient location or at a more convenient rate. Some of the most effective heat dissipation devices achieve this end through the use of liquid coolants.

U.S. Pat. No. 9,443,786 (“the '786 patent”) describes a liquid-cooled heat dissipation device that features a serpentine fin structure (serving as a heat exchange surface) in thermal communication with one or more power semiconductor devices via thermally conductive plates. The serpentine fin structure in the '786 patent is situated between an upper and lower plenum within a manifold that features an influent and an effluent located proximate to the opposing distal ends of the manifold such that cooling fluid that enters the manifold through the influent must travel past the serpentine fin structure before exiting through the effluent. The '786 patent is incorporated by reference in its entirety into this specification, including the abstract, entire specification, drawings, and claims.

In the apparatus disclosed and claimed in the '786 patent, heat energy that is generated in the power semiconductor devices flows from the point of generation (the power semiconductor) to the serpentine fin structure and is then transferred from the surface of the serpentine fin structure to the cooling fluid as the cooling fluid flows past and is carried away through the effluent for ultimate dissipation or dispersion elsewhere.

Soon after the design disclosed and claimed in the '786 patent was developed it became apparent that the thermal efficiency of the design could be further improved by more precisely controlling the cooling fluid pressure to ensure uniform flow distribution across the heat exchange surface, or in some applications, to create intentionally non-uniform flow distributions. This was achieved by introducing flow balancers which were disclosed and claimed in U.S. patent application Ser. No. 15/787,711 (“the '711 application”). The '711 application is incorporated by reference in its entirety into this specification, including the abstract, entire specification, drawings, and claims.

The apparatus disclosed in the '711 application is a definite improvement over the apparatus disclosed in the '786 patent; however, there still exists room for further improvements. One area in which the design can be still further improved is in its ability to accommodate surface-mount power semiconductor devices as opposed to the legacy leaded power semiconductor devices featured in the designs of the '786 patent and '711 application.

Accommodating surface-mount power semiconductors is important for several reasons. To begin with, surface-mount packaging is the more predominately favored packaging configuration among the newest and most advanced power semiconductors so being capable of accommodating such packaging configuration is likely to be increasingly important in the future.

Further, such surface-mount technology is often lower profile and typically exhibits greater electrical and thermal efficiency than legacy packaging configurations, which, as previously stated, depending on the performance demands of the overall application, may provide the device with critical operating advantages such as longer operating life, lower power consumption, higher power tolerance or endurance, and/or may even allow the overall device to be redesigned to exhibit a physically smaller footprint. Such advantages are critically important in highly competitive fields.

Still further, when compared to legacy leaded power semiconductor devices, surface-mount power semiconductor devices often exhibit lower lead resistance and significantly less stray inductance because of the absence of lengthy parallel leads.

There exists a need to further improve and modify the heat dissipation devices disclosed and claimed in both the '786 patent and the '711 application to accommodate surface-mount power semiconductors and realize the efficiency advantages such power semiconductor devices provide.

The present disclosure distinguishes over the related art providing heretofore unknown advantages as described in the following summary.

### BRIEF SUMMARY OF THE INVENTION

The present disclosure describes an improved innovative heat dissipation apparatus for power semiconductor devices. Improving upon the legacy designs disclosed in the '786 patent and the '711 application, the presently disclosed apparatus features design modifications that allow for the accommodation of surface-mount power semiconductor devices. Such design modifications are highly important as the accommodation of the surface-mount configuration allows for the utilization of the most advanced power semiconductor devices as power semiconductors are increasingly being packaged in surface-mounted configurations. Further, the surface-mount packaging configurations provide several important electrical and thermal performance advantages.

Similar to the apparatuses disclosed in both the '786 patent and the '711 application, the presently disclosed apparatus includes a manifold with an influent that leads to a first plenum and effluent that draws from a second plenum and features a serpentine fin structure or similar heat exchange surface located within the manifold between the first and second plenum such that coolant fluid must flow across the serpentine fin structure or heat exchange surface to flow through and exit the apparatus.

However, unlike the legacy designs in which leaded power semiconductors are affixed to a thermally conductive plate but are in direct electrical communication with the printed circuit board, or other surface on which the legacy apparatus is mounted, via a plurality of leads originating from the power semiconductor device, the presently disclosed improved apparatus features at least one surface-mount power semiconductor device mounted directly to at least one direct bond copper (DBC) substrate such that the DBC substrate is in both electrical and thermal communication with the power semiconductor device. The DBC is typically a laminated plate comprising a thin insulating ceramic core with copper laminated on one or both sides of the core. The copper layer(s) may be etched to provide an electrical circuit. Each DBC substrate features at least two short copper or aluminum leads that are attached to the DBC substrate via welding or high temperature solder or brazing such that the power semiconductor is in electrical communication with a printed circuit board via the DBC substrate. The leads attached to the DBC may be thicker and shorter than the typical leads featured in leaded semiconductor packages thereby providing the advantage of being capable of high current with relatively low electrical resistance and low stray inductance when compared to legacy leaded devices.

The DBC substrate is in thermal communication with a serpentine fin structure or similar heat exchange surface either via direct contact or through a copper or aluminum plate.

The presently disclosed design improvements increase the viability of the apparatuses disclosed in the '786 patent and the '711 application by accommodating the increasingly popular surface-mount packaging technology and the accompanying efficiencies.

This disclosure teaches certain benefits in construction and use which give rise to the objectives described below:

A primary objective inherent in the above described apparatus and method is to provide advantages not taught by the prior art;

Another objective is to provide a power semiconductor heat dissipation apparatus with the ability to accommodate surface-mount power semiconductor devices;

A further objective is to provide a power semiconductor heat dissipation apparatus with the ability to accommodate the predominate packaging configuration of the most advanced power semiconductor devices;

A still further objective is to provide a power semiconductor heat dissipation apparatus with improved lead resistance and stray inductance;

Other features and advantages of the present invention will become apparent from the following more detailed descriptions, taken in conjunction with the accompanying drawings, which illustrate, by way of example, the principles and features of the presently described apparatus.

### BRIEF DESCRIPTION OF THE SEVERAL VIEWS OF THE DRAWINGS

The accompanying drawings illustrate various exemplary implementations and are part of the specification. The illustrated implementations are proffered for purposes of example not for purposes of limitation. Illustrated elements will be designated by numbers. Once designated, an element will be identified by the identical number throughout. Illustrated in the accompanying drawing(s) is at least one of the best mode embodiments of the present disclosure. In such drawing(s):

FIG. 1 is a perspective view of an exemplary embodiment of the presently disclosed improved heat dissipation apparatus for surface-mount power semiconductor devices.

FIG. 2 is a simplified perspective diagram of the serpentine fin structure serving as a heat dissipation surface which is in thermal communication with surface-mounted power semiconductor devices (power semiconductor devices not visible from this perspective).

FIG. 3 is a simplified side plan view diagram of the serpentine fin structure in thermal communication with a plurality of thermally conductive plates (DBC plates), and a plan view diagram of a plurality of surface-mount power semiconductors affixed to thermally conductive plates, each plate featuring at least two short copper or aluminum leads.

FIG. 4 is a cut-away perspective view of an exemplary embodiment of the presently disclosed improved heat dissipation apparatus for surface-mount power semiconductor devices illustrating the serpentine fine structure in thermal communication with the externally affixed surface-mounted power semiconductor devices.

FIG. 5 is a perspective view of an exemplary embodiment of the presently disclosed improved heat dissipation apparatus for surface-mount power semiconductor devices.

### DETAILED DESCRIPTION OF THE EXEMPLARY EMBODIMENT

The above described drawing figures illustrate an exemplary embodiment of the presently disclosed apparatus and its many features in at least one of its preferred, best mode embodiments, which is further defined in detail in the following description. Those having ordinary skill in the art may be able to make alterations and modifications to what is described herein without departing from its spirit and scope of the disclosure. Therefore, it must be understood that what is illustrated is set forth only for the purposes of example and that it should not be taken as a limitation in the scope of the present apparatus or its many features.

Described now in detail is an improved heat dissipation apparatus for power semiconductor devices configured to accommodating surface-mount devices.

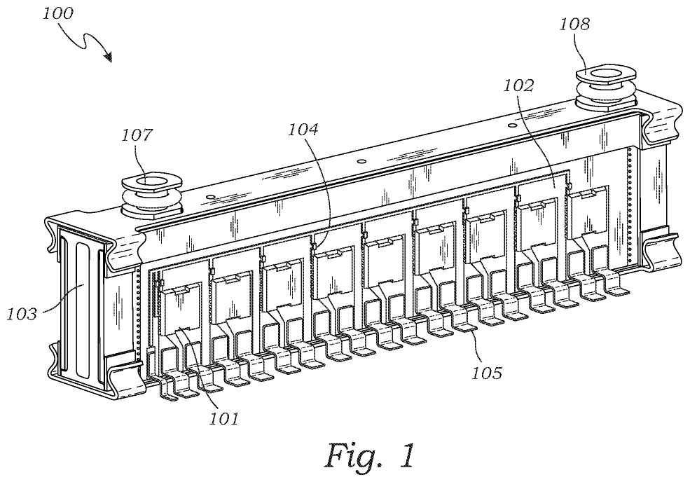

FIG. 1 illustrates an exemplary embodiment of the presently disclosed apparatus 100 illustrating an influent 107 through which cooling fluid may enter the apparatus, an effluent through which cooling fluid may exit the apparatus 108, plurality surface mount power semiconductor devices 101 mounted directly on direct bond copper (DBC) substrate plates 102, and short, high-current leads 105 attached to the DBC substrate plate 102. DBC plate 102 may be a single substrate or multiple plates. Furthermore, DBC plate 102 may be etched to form electrical circuits and additional devices such as resistors and capacitors, shown as item 104, may also be mounted on the DBC plate 102. Semiconductor devices 101 are attached via soldering or sintering to the outer surface of the DBC plate 102. The fluid plenum 103 provides the main structure of the assembly as well as the fluid passages.

The leads 105 are made of aluminum or copper and attached to the DBC substrate plates 102 by ultrasonic welding, high temperature soldering or brazing, or similar process. One advantage such configuration provides over legacy designs is lower resistance and lower stray inductance due to the relative shortness and thickness of the leads 106.

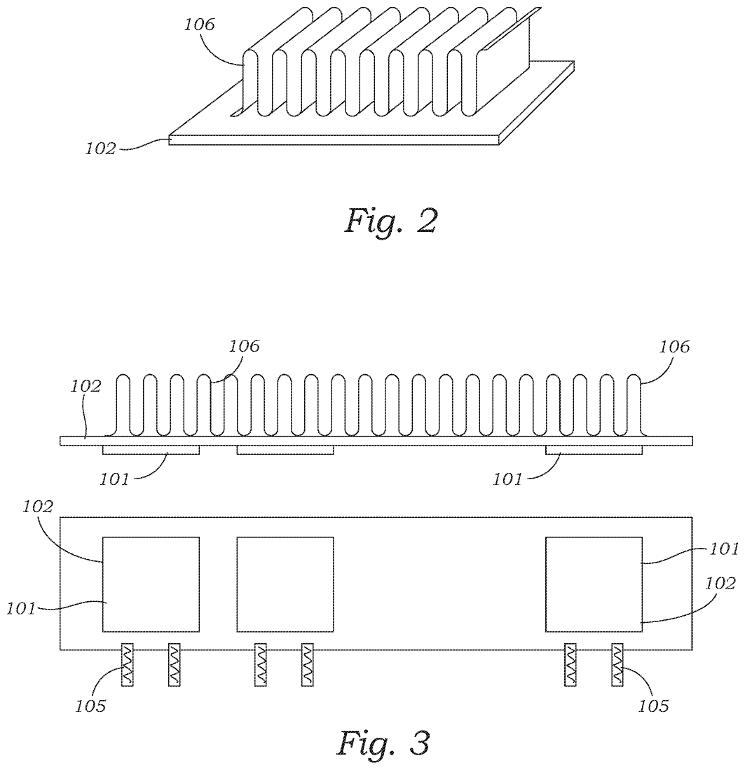

FIG. 2 is a diagram illustrating an exemplary embodiment of the serpentine fin structure or similar heat exchange surface 106. The diagram illustrates that the serpentine fin structure or similar heat exchange surface 106 is in contact with the DBC plate 102. In some embodiments, such as high pressure applications, a copper or aluminum plate may be used between the fin structure 106 and DBC plate 102.

FIG. 3 illustrates side and plan views of the same diagram illustrated in FIG. 2. The side view further illustrates that the surface mount semiconductor devices 101 are affixed to the opposing side of the DBC 102 as the serpentine fin structure or similar heat exchange surface 106. The proximity is important as this is the thermal path by which the heat energy is removed. The material chosen for the DBC 102 will affect the efficiency of the heat removal path.

FIG. 3 also illustrates a plan view diagram of a plurality of surface mount power semiconductor devices 101 mounted directly on the DBC substrate plate 102, featuring short high current leads 105. Different embodiments may include different numbers of power semiconductor devices, the illustration is for exemplar only and is not meant to be limiting.

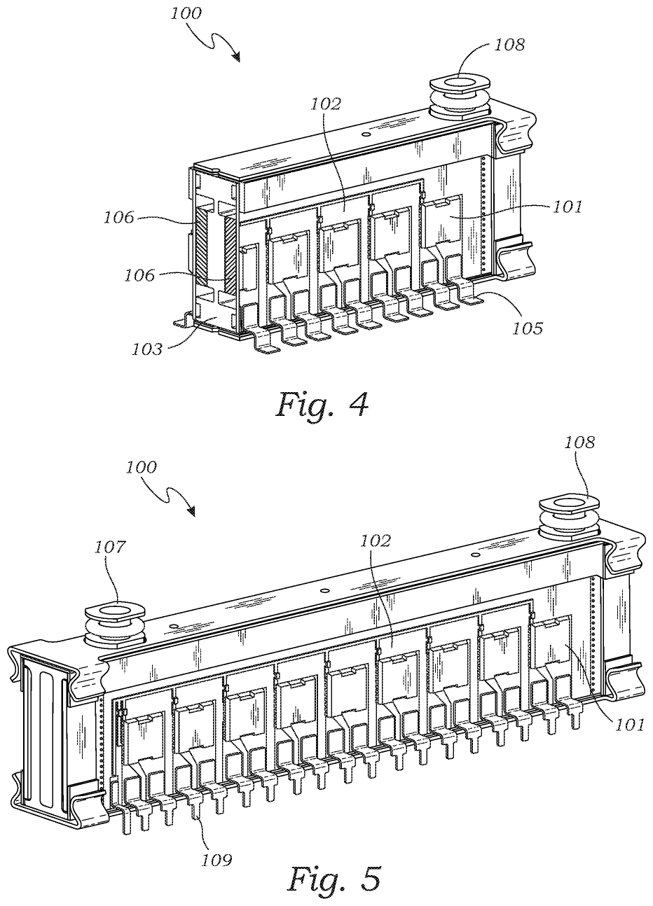

FIG. 4 depicts a cut-away embodiment of the presently disclosed apparatus illustrating the serpentine fin structure or similar heat exchange surface 106 in the center of the manifold 103 directly on the opposing side of the DBC substrate plate 102 thereby facilitating the efficient removal of heat energy from the surface mount power semiconductor device 101 which is the source of the heat energy.

FIG. 4 also illustrates the high current leads 106 shaped for a surface mount configuration which provide electrical communication from a printed circuit board or other surface to the power semiconductor device 101 via the DBC substrate plate 102.

FIG. 5 illustrates an exemplar embodiment of the presently disclosed improved apparatus featuring leads 109 shaped for through-hole configuration coupling with a printed circuit board. Other embodiments such as screw terminal connection are possible as well.

The enablements described in detail above are considered novel over the prior art of record and are considered critical to the operation of at least one aspect of the apparatus and its method of use, and to the achievement of the above-described objectives. The words used in this specification to describe the instant embodiments are to be understood not only in the sense of their commonly defined meanings, but to include by special definition in this specification: structure, material, or acts beyond the scope of the commonly defined meanings. Thus, if an element can be understood in the context of this specification as including more than one meaning, then its use must be understood as being generic to all possible meanings supported by the specification and by the word(s) describing the element.

The definitions of the words or drawing elements described herein are meant to include not only the combination of elements which are literally set forth, but all equivalent structures, materials or acts for performing substantially the same function in substantially the same way to obtain substantially the same result. In this sense it is therefore contemplated that an equivalent substitution of two or more elements may be made for any one of the elements described and its various embodiments or that a single element may be substituted for two or more elements in a claim.

Changes from the claimed subject matter as viewed by a person with ordinary skill in the art, now known or later devised, are expressly contemplated as being equivalents within the scope intended and its various embodiments. Therefore, substitutions, now or later known to one with ordinary skill in the art, are defined to be within the scope of the defined elements. This disclosure is thus meant to be understood to include what is specifically illustrated and described above, what is conceptually equivalent, what can be obviously substituted, and also what incorporates the essential ideas.

The scope of this description is to be interpreted only in conjunction with the appended claims and it is made clear, here, that each named inventor believes that the claimed subject matter is what is intended to be patented.

What is claimed is:

1. An improved power semiconductor heat dissipation apparatus, said apparatus comprising:
a manifold comprising:
an influent through which coolant fluid may enter the manifold;
an effluent through which coolant may exit the manifold;
a heat exchange surface located within the manifold;
a first plenum defined by the space within the manifold between the influent and the heat exchange surface;
a second plenum defined by the space within the manifold between the heat exchange surface and the effluent;
at least one direct bond copper plate in thermal communication with the heat exchange surface, said direct bond copper plate featuring at least two leads;
at least one power surface-mount semiconductor mounted on the direct bond copper plate.
wherein said heat exchange surface is situated within said manifold between said first plenum and said second plenum such that cooling liquid must pass through said heat exchange surface to flow from said first plenum to said second plenum;

2. An apparatus as in claim 1 wherein said at least two leads affixed to the direct bond copper plate are short, high current connections;

3. An apparatus as in claim 2 wherein said at least two leads affixed to direct bond copper plate are shaped to be connected to a printed circuit board via a surface mount configuration;

4. An apparatus as in claim 3 wherein said at least two leads affixed to direct bond copper plate are shaped to be connected to a printed circuit board via a through hole configuration;

5. An apparatus as in claim 4 wherein said at least two leads affixed to direct bond copper plate are shaped to be connected to a printed circuit board via a screw terminal configuration;
